(19) United States
(12) Patent Application Publication
(10) Pub. No.: US 2024/0198312 A1
(43) Pub. Date: Jun. 20, 2024

(54) METHOD OF MODIFYING PARTICLES USING A CASCADE PLASMA REACTOR

(71) Applicant: Technology Innovation Institute-Sole Proprietorship LLC, Masdar City (AE)

(72) Inventor: Zineb Matouk, Masdar City (AE)

(73) Assignee: Technology Innovation Institute-Sole Proprietorship LLC, Masdar City (AE)

(21) Appl. No.: 18/390,038

(22) Filed: Dec. 20, 2023

Related U.S. Application Data
(60) Provisional application No. 63/476,220, filed on Dec. 20, 2022.

(51) Int. Cl. B01J 19/08; B01J 19/24

(52) U.S. Cl. CPC B01J 19/088; B01J 19/245; B01J 2219/00452; B01J 2219/0809; B01J 2219/0841; B01J 2219/0894

(57) ABSTRACT

The present disclosure describes a cascade reactor which includes a first reactor sector including a first starting material inlet, a first modifier inlet, a first dielectric barrier discharge, and a first collection outlet; a second reactor sector, connected to the first reactor sector by a connection, including a second starting material inlet, a second modifier inlet, a second dielectric barrier discharge, and a second collection outlet; and insulating reactor support surrounding the first reactor sector and the second reactor sector, a gas line for providing a gas to the first reactor sector and the second reactor sector, and a housing enclosing the first reactor sector, the second reactor sector, and the gas line. Methods of operating the cascade reactor and modifying particles using the cascade reactor are also described.

### CROSS-REFERENCE TO RELATED APPLICATIONS

This application claims priority to U.S. Provisional Patent Application No. 63/476,220, which was filed on Dec. 20, 2022, the entire contents of which are incorporated by reference herein.

### FIELD

The present disclosure relates generally to methods of modifying particles. More specifically, this disclosure related to the scalable use of cascade reactors to modifying particles.

### BACKGROUND

Micro- and nanoparticles are used in numerous fields, such as consumer products, automotive industries, biomedical and tissue engineering, and other areas. These small particles can be used for the monitoring of molecular-level events, the targeted treatment of disease, and the fine tuning of energy generation and storage devices, among other applications.

In order to obtain functional micro- and nanoparticles that are designed for specific applications, there is a need for reliable methods of producing such particles. In particular, surface modifications to micro- and nanoparticles are useful in designing particles with specific properties. The ability to perform multiple treatments so as to produce multifunctional particles is of particular interest for fields with specialized requirements.

Several approaches to modifying particles are known, though typically each type of particle modification requires a specialized method and reaction set-up. Conventional chemical surface treatments suffer from disadvantages such as risk of contamination, chemical storage and waste disposal, and high cost of operating systems. Plasma methods have been investigated for the surface modification of particles as an environmentally friendly and scalable alternative to chemical surface treatments. In particular, dielectric barrier discharge (DBD) is a target of interest, operable at atmospheric pressures and relatively low temperatures. A dielectric barrier discharge is a plasma resulting from an electrical discharge between two electrodes separated by a dielectric barrier. Numerous configurations for dielectric barrier discharges are possible, and it is common for reactor designs to be highly tailored to a specific function. There remains a need for methods and reactors that can functionalize a variety of particles with a variety of modifiers, and allow for the introduction of multiple modifiers, simultaneously or sequentially, to produce multifunctional particles.

### SUMMARY

In aspects, the techniques described herein relate to a cascade reactor, including: a first reactor sector including: a first starting material inlet, a first modifier inlet, a first dielectric barrier discharge, and a first collection outlet; a second reactor sector, connected to the first reaction by a connection, including: a second starting material inlet, a second modifier inlet, a second dielectric barrier discharge, and a second collection outlet; an insulating reactor support surrounding the first reactor sector and the second reactor sector, a gas line for providing a gas to the first reactor sector and the second reactor sector, and a housing enclosing the first reactor sector, the second reactor sector, and the gas line.

In aspects, the techniques described herein relate to a cascade reactor according to any of the above aspects, wherein the first starting material inlet and the second starting material inlet each independently include a worm screw system, a sonication system, a tapping system, a powder sieving and blending system, or combinations thereof. In aspects, the techniques described herein relate to a cascade reactor, wherein the first dielectric barrier discharge and the second dielectric barrier discharge each include a first electrode, a second electrode, and a dielectric material. In aspects, the techniques described herein relate to a cascade reactor according to any of the above aspects, wherein the first electrode and the second electrode each independently include a metal plate, a metal foil, a metal wire, a metal mesh, a metal spiral, a metal bolt, or a metallic paint. In aspects, the techniques described herein relate to a cascade reactor according to any of the above aspects, wherein the first electrode is a high voltage electrode. In aspects, the techniques described herein relate to a cascade reactor according to any of the above aspects, wherein the second electrode is a grounded electrode. In aspects, the techniques described herein relate to a cascade reactor according to any of the above aspects, wherein the second electrode includes a metal plate, a metal foil, a metal wire, a metal mesh, a metal spiral, a metal bolt, or a metallic paint.

In aspects, the techniques described herein relate to a cascade reactor according to any of the above aspects, further including: a third reactor sector, enclosed within the housing and surrounded by the insulating reactor support, including: a third starting material inlet, a third modifier inlet, a third dielectric barrier discharge, and a third collection outlet. In aspects, the techniques described herein relate to a cascade reactor according to any of the above aspects, wherein the third dielectric barrier discharge includes a first electrode and a second electrode.

In aspects, the techniques described herein relate to a method of operating a cascade reactor, including introducing particles into the reactor, treating the particles to form modified particles, and collecting the modified particles. In aspects, the techniques described herein relate to a method according to any of the above aspects, wherein the particles are microparticles, nanoparticles, or combinations thereof. In aspects, the techniques described herein relate to a method according to any of the above aspects, wherein treating the particles includes coating the particles with a coating material, functionalizing the surface of the particles, etching the particles, cleaning the particles, or combinations thereof. In aspects, the techniques described herein relate to a method according to any of the above aspects, wherein collecting the particles includes removing the particles from the reactor.

In aspects, the techniques described herein relate to a method of modifying particles, including introducing the particles into a reactor, generating a dielectric barrier discharge plasma at atmospheric pressure within the reactor, performing a first treatment on the particles with the dielectric barrier discharge plasma to form modified particles, and collecting the modified particles. In aspects, the techniques described herein relate to a method, wherein the particles are microparticles, nanoparticles, or combinations thereof.

In aspects, the techniques described herein relate to a method according to any of the above aspects, wherein the first treatment includes coating the particles with a coating material, functionalizing the surface of the particles, etching the particles, cleaning the particles, or combinations thereof. In aspects, the techniques described herein relate to a method, wherein the particles include silica, cellulose, polymers, titanium dioxide, carbon nanotubes, or combinations thereof. In aspects, the techniques described herein relate to a method, wherein the coating material includes methane, ammonia, silane, acetylene, ethylene, isoprene, hexamethyldisiloxane, tetraethyloxysilane, tetraethyl oxysilicane, diethyl dimethyl siloxane, 1,3-butadiene, styrene, methyl methacrylate, tetrafluoroethelyne, methane, ethane, propane, butane, pentane, hexane, cyclohexane, acetylene, ethylene, propylene, benzene, isoprene, hexamethyldisiloxane, tetraethyloxysilane, tetraethyl oxysilicane, diethyl dimethyl siloxane, 1,3-butadiene, styrene, methyl methacrylate, tetrafluoroethelyne, pyrrole, cyclohexane, 1-hexene, allylamine, acetyl acetone, ethylene oxide, glycidyl methacrylate, acetonitrile, tetrahydrofuran, ethyl acetate, acetic anhydride, aminopropyl trimethoxysilane, aminopropyl triethoxysilane, triethoxyvinyl silane, loctanol, acrylic acid, ferrocene, cobaltocene, cyclooctatetraene iron tricarbonyl, methyl cyclopentadienyl iron dicarbonyl, dicyclopentadienyl iron dicarbonyl dimmer, cyclopentadienyl cobalt, cobalt acetylacetonate, nickel acetylacetonate, dimethyl-(2,4-pentane-dionato) gold (III), nickel carbonyl, iron carbonyl, tin acetylacetonate, indium-acetylacetonate and indium tetramethylheptanedionate, nitrous acid, or combinations thereof. In aspects, the techniques described herein relate to a method according to any of the above aspects, wherein functionalizing the surface of the particles includes increasing the hydrophobicity, hydrophilicity, or surface activation of the surface of the particles. In aspects, the techniques described herein relate to a method according to any of the above aspects, wherein functionalizing the surface of the particles includes decreasing the hydrophobicity, hydrophilicity, or surface activation of the surface of the particles relative to unmodified particles. In aspects, the techniques described herein relate to a method according to any of the above aspects, wherein collecting the particles includes removing the particles from the reactor. In aspects, the techniques described herein relate to a method according to any of the above aspects, further including performing a second treatment on the particles with the dielectric barrier discharge plasma.

### BRIEF DESCRIPTION OF THE DRAWINGS

Aspects, features, benefits, and advantages of the embodiments described herein will be apparent with regard to the following description, appended claims, and accompanying drawings where:

FIG. 1 is an illustrative diagram of a cascade reactor, according to an embodiment of the present disclosure.

FIG. 2 is a flow chart describing the steps of a method of modifying particles, according to an embodiment of the present disclosure.

FIG. 3A is an image of a water droplet on a surface of untreated silicon dioxide nanoparticles.

FIG. 3B is an image of a water droplet on a surface of modified silicon dioxide nanoparticles, according to an embodiment of the present disclosure.

FIG. 3C is an image of a water droplet on a surface of modified silicon dioxide nanoparticles, according to an embodiment of the present disclosure.

FIG. 3D is an image of a water droplet on a surface of modified silicon dioxide nanoparticles, according to an embodiment of the present disclosure.

FIG. 4A is an image of a water droplet on a surface of untreated titanium dioxide nanoparticles.

FIG. 4B is an image of a water droplet on a surface of modified titanium dioxide nanoparticles, according to an embodiment of the present disclosure.

FIG. 4C is an image of a water droplet on a surface of modified titanium dioxide nanoparticles, according to an embodiment of the present disclosure.

FIG. 4D is an image of a water droplet on a surface of modified titanium dioxide nanoparticles, according to an embodiment of the present disclosure.

### DETAILED DESCRIPTION

The present disclosure describes a cascade reactor which includes multiple dielectric barrier discharges. The reactor described herein can be used to produce multifunctional micro- and nanoparticles which have undergone one or more surface treatments and/or coatings. The ability to perform multiple modifications within one reactor, such that the particles undergo a first treatment using a first modifier and subsequently a second treatment using a second modifier, is particularly advantageous. The reactor of the present disclosure can further include an optional third modifier for an optional third treatment. The systems of the prior art do not permit multiple sequential treatments of particles within one system, and instead require performing a first treatment with a first modifier and removing the particles from the reactor, and subsequentially changing the reactor parameters and modifier before performing a second treatment. The present design includes a cascade of reactor sectors wherein multiple treatments may be performed in one reactor without needing to remove the particles between treatments. The present reactor includes a gas line to a gas mixture which is easily controllable and interchangeable, further contributing to the ease of performing multiple treatments on the particles. The use of dielectric barrier discharge plasma (which is a pulse plasma) allows a longer plasma lifetime for more thorough particle treatment, and further permits operation at atmospheric pressure and lower temperatures than other surface treatment apparatuses.

Methods of modifying micro- and nanoparticles using the reactor disclosed herein are also described. As described above, the methods described herein permit multiple treatments to be performed on the particles. Using dielectric barrier discharge plasma permits the surface functionalization of particles without altering the bulk properties and avoids costly and hazardous chemical methods. Modifying particles via the present method is exceptionally fast, on the order of seconds, and yields are high. Previous methods of modifying particles with plasma result in a yield of approximately 50%, due in part to particles attaching to the internal components of the reactor where they are unable to be collected. The present method addresses this deficiency and achieves higher yield of modified particles by using a gas flow from multiple directions to keep the nanoparticles suspended in the plasma. The gas flow used in the present reactor and method is not particularly limited, and may be measured in standard cubic centimeters per minute (SCCM) or standard liters per minute (SLM). The particles to be modified are not particularly limited, and a range of surface modifications may be achieved with the present method.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

As used herein, the term “about” means plus or minus 10% of the numerical value of the number with which it is being used. For example, “about 50%” means in the range of 45-55% and also includes exactly 50%. Stated differently, any value disclosed herein as being modified by “about” also discloses the exact value.

As used herein, the term “atmospheric pressure” refers to pressures between approximately 0.05 atm and 5 atm.

As used herein, “low frequency” refers to frequencies of about 1 MHz or less.

As used herein, the term “surface treatment” refers to a modification of the surface of a material or particle, wherein the surface of the material or particle may be coated with a coating material or the surface may react such that the surface of a treated material or particle is distinct from the surface of an untreated material or particle. Surface treatments may include, but are not limited to, surface functionalization, surface etching, surface cleaning, surface activation, the like, or combinations thereof.

As used herein, the term “modifier” refers to any compound, coating material, or reactant that reacts with an untreated particle to form a treated or modified particle.

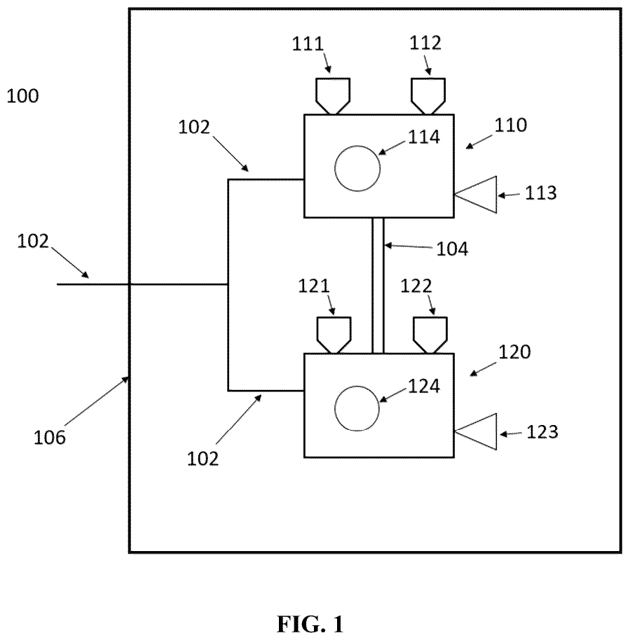

In embodiments, there is provided a cascade reactor 100. FIG. 1 is an illustrative diagram of a cascade reactor, according to an embodiment of the present disclosure. The cascade reactor 100 may include a gas line 102, a first reactor sector 110, which may include a first starting material inlet 111, a first modifier inlet 112, a first collection outlet 113, and a first dielectric barrier discharge 114. The cascade reactor 100, in embodiments, includes a second reactor sector 120, which may include a second starting material inlet 121, a second modifier inlet 122, a second collection outlet 123, and a second dielectric barrier discharge 124. In embodiments, the cascade reactor 100 includes a connection 104 between the first reactor sector 110 and the second reactor sector 120. In embodiments, the gas line 102, the first reactor sector 110, the second reactor sector 120, and the connection 104 are contained within a housing 106.

In embodiments, the cascade reactor 100 includes a gas line 102 for providing a gas to the first reactor sector and the second reactor sector. In embodiments, the gas line 102 is configured to deliver gaseous argon, nitrogen, helium, methane, silane, or combinations thereof to the cascade reactor 100. The dimensions and material of the gas line 102 are not particularly limited and may be selected by an individual skilled in the art. In embodiments, the gas line 102 includes multiple individual lines, splitters, valves, or other components that allow gas to be delivered to the reactor sectors as described herein. In embodiments, the gas line 102 is configured such that the gas line delivers gas to the reactor sectors from multiple directions so as to keep the particles suspended in plasma for a period of time sufficient to treat all or a majority of the particles, thereby obtaining a high yield of treated particles.

In embodiments, the cascade reactor 100 includes a first reactor sector 110. The first reactor sector 110 can, in embodiments, include a first starting material inlet 111. The first starting material inlet 111 allows the starting material to be introduced into the reactor. In embodiments, the first starting material inlet 111 is a worm screw system, a sonication system, a tapping system, a powder sieving and blending system, or combinations thereof. Other types of inlets familiar to those skilled in the art are also contemplated. In embodiments, the starting material includes untreated particles, such as microparticles, nanoparticles, or combinations thereof. Particles may be injected, poured, or otherwise introduced into the reactor through the first starting material inlet 111. In embodiments, the first reactor sector 110 also includes a first modifier inlet 112. The first modifier inlet 112 allows a modifier (such as a coating material or other reactant) to be introduced into the reactor, such that the modifier reacts with the starting material to form treated particles. In embodiments, the first reactor sector 110 includes a first collection outlet 113, wherein the treated particles may be collected and removed from the reactor. In embodiments, the first collection outlet 113 includes filter paper, a sieve, a size exclusion filter, or other means of controlling the collection of particles from the reactor. In embodiments, the first reactor sector 110 is surrounded by an insulating reactor support. In embodiments, the insulating reactor support includes a non-conductive material, such as, for example, plastics, ceramics, glass, rubber, or other non-conductive materials familiar to those skilled in the art.

In embodiments, the first reactor sector 110 also includes a first dielectric barrier discharge 114. The first dielectric barrier discharge 114 may, in embodiments, catalyze, initiate, or otherwise permit the functionalization of starting material particles with the modifier. In embodiments, the first dielectric barrier discharge 114 operates at atmospheric pressure. In embodiments, the first dielectric barrier discharge 114 includes a first electrode and a second electrode, which are in aspects separated by a dielectric barrier. Dielectric Barrier Discharge (DBD) is a discharge that occurs when an AC voltage is applied to one or both electrodes, which are in embodiments made of two metal plates and covered with or separated by a dielectric material. The dielectric material acts in the same way as a capacitor. In embodiments, the dielectric barrier includes glass, quartz, ceramics, enamel, mica, plastics, silicon dioxide, silicon nitride, rubber, polytetrafluoroethylene (such as commercially available under the name Teflon), or combinations thereof. In embodiments, the first electrode and the second electrode each independently include a metal plate, a metal foil, a metal wire, a metal mesh, a metal spiral, a metal bolt, or a metallic paint. In embodiments, the first electrode and the second electrode have the same composition and form; in embodiments, the first electrode and the second electrode have a different composition and form. In embodiments, the first electrode is a high voltage electrode. In embodiments, the second electrode is a grounded electrode. The metal selected for the second electrode is not particularly limited. In embodiments, the metal includes titanium, chromium, cobalt, nickel, palladium, platinum, copper, silver, gold, zinc, or combinations thereof. The dielectric barrier discharge 114 generates a plasma at high voltage and atmospheric pressure that, in embodiments, is responsible for the surface treatment of particles. In embodiments, particles undergo a first modification in the first reactor sector 110. In embodiments, the cascade reactor 100 and its components as described herein are configured in such a way that the particles are suspended in the plasma for a sufficiently long period of time so as to uniformly treat all or a majority of the particles and obtain a high yield of treated particles.

In embodiments, the cascade reactor 100 includes a second reactor sector 120. In embodiments, the second reactor sector 120 includes the same types of components as the first reactor sector 110, as described herein. For example, the second reactor sector 120 may include, in embodiments, a second starting material inlet 121, a second modifier inlet 122, a second collection outlet 123, and a second dielectric barrier discharge 124. The second dielectric barrier discharge 124 may include two electrodes as described herein, separated by a dielectric barrier as further described herein. In embodiments, the second reactor sector 120 is surrounded by an insulating reactor support. In embodiments, particles undergo a second modification in the second reactor sector 120. In embodiments, the presence of the second reactor sector 120 allows multiple modifications to be performed on the particles, as opposed to other reactors which only allow one modification to particles per use.

In embodiments, the cascade reactor 100 includes a connection 104 which connects the first reactor sector 110 and the second reactor sector 120. In embodiments, the connection 104 includes polytetrafluoroethylene, a metal, or other suitable connection material as determined by one skilled in the art. In embodiments, the connection 104 allows particles which have undergone a first modification in the first reactor sector 110 to move to the second reactor sector 120, where the particles undergo a second modification.

In embodiments, the cascade reactor 100 includes a housing 106. In embodiments, the first reactor sector 110, the second reactor sector 120, the gas line 102, and the connection 104 are enclosed within the housing 106.

In embodiments, the cascade reactor 100 includes a third reactor sector, which may include a third starting material inlet, a third modifier inlet, a third collection outlet, and a third dielectric barrier discharge. The third reactor sector may be connected to the second reactor sector by a second connection, according to embodiments of the present disclosure, such that particles which have undergone a first modification and a second modification can be moved to the third reactor sector. In embodiments, the gas line 102 provides gas to the third reactor sector. In embodiments, the third reactor sector is surrounded by an insulating reactor support and contained within the housing 106. In embodiments, a third reactor sector is not included in the cascade reactor 100. It is further contemplated that the cascade reactor 100 may include a fourth reactor sector, a fifth reactor sector, and so forth, which each include the components of the reactor sectors described herein.

In embodiments, there is provided a method of operating the cascade reactor described herein, including steps of providing particles, introducing the particles into the reactor, treating the particles to form modified particles, and collecting the modified particles. In embodiments, the particles include microparticles, nanoparticles, or combinations thereof. In embodiments, treating the particles to form modified particles includes coating the particles with a coating material, functionalizing the surface of the particles, or combinations thereof. In embodiments, collecting the particles includes removing the particles from the reactor. In embodiments, the active species in the plasma (which may include photons, ions, molecules, excited atoms, or combinations thereof) make it possible to break chemical bonds on the surface of the particles. In embodiments, the depth of penetration of such a process is on the order of hundreds of nanometers. In addition, the same active species can react with each other and/or with free radicals o the surfaces of the particles to give rise to a new surface layer with a chemical composition different from the previous one. Additionally, the active species can lead to the formation of volatile species capable of removing a thin layer of the starting material such that the surfaces of the particles are etched or refreshed.

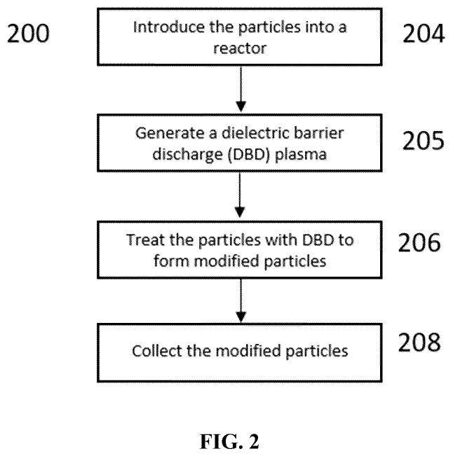

In embodiments, there is provided a method 200 of modifying particles. FIG. 2 is a flow chart describing the steps of a method of modifying particles, according to an embodiment of the present disclosure. In embodiments, the method 200 includes introducing the particles into a reactor 204, generating a dielectric barrier discharge plasma at atmospheric pressure within the reactor 205, performing a first treatment on the particles with the dielectric barrier discharge plasma to form modified particles 206, and collecting the modified particles 208.

In embodiments, the particles which are modified in the disclosed method are microparticles, nanoparticles, or combinations thereof. In embodiments, the particles include silica, cellulose, polymers, titanium dioxide, carbon nanotubes, or combinations thereof. It is contemplated that other micro- and nanoparticles familiar to those skilled in the art may also be modified by the methods of the present disclosure.

In embodiments, introducing the particles into a reactor 204 includes pouring, injecting, or otherwise introducing the particles in the reactor. In embodiments, the reactor is the cascade reactor as described herein. In embodiments, the particles are introduced into the reactor through a starting material inlet.

In embodiments, generating a dielectric barrier discharge plasma at atmospheric pressure 205 includes applying a voltage between a first electrode and a second electrode separated by a dielectric material. In embodiments, the first electrode is a high voltage electrode, and the second electrode is a grounded electrode. In embodiments, the dielectric material includes glass, quartz, ceramics, enamel, mica, plastics, silicon dioxide, silicon nitride, rubber, polytetrafluoroethylene, or combinations thereof. Applying the voltage may be carried out by any method known to those skilled in the art. For example, a high voltage amplifier may be employed in embodiments.

In embodiments, treating the particles to form modified particles 206 includes coating the particles with a coating material, functionalizing the surface of the particles, etching the particles, cleaning the particles, or combinations thereof. In embodiments, the coating material includes methane, ammonia, silane, acetylene, ethylene, isoprene, hexamethyldisiloxane, tetraethyloxysilane, tetraethyl oxysilicane, diethyl dimethyl siloxane, 1,3-butadiene, styrene, methyl methacrylate, tetrafluoroethelyne, methane, ethane, propane, butane, pentane, hexane, cyclohexane, acetylene, ethylene, propylene, benzene, isoprene, hexamethyldisiloxane, tetraethyloxysilane, tetraethyl oxysilicane, diethyl dimethyl siloxane, 1,3-butadiene, styrene, methyl methacrylate, tetrafluoroethelyne, pyrrole, cyclohexane, 1-hexene, allylamine, acetyl acetone, ethylene oxide, glycidyl methacrylate, acetonitrile, tetrahydrofuran, ethyl acetate, acetic anhydride, aminopropyl trimethoxysilane, aminopropyl triethoxysilane, triethoxyvinyl silane, loctanol, acrylic acid, ferrocene, cobaltocene, cyclooctatetraene iron tricarbonyl, methyl cyclopentadienyl iron dicarbonyl, dicyclopentadienyl iron dicarbonyl dimmer, cyclopentadienyl cobalt, cobalt acetylacetonate, nickel acetylacetonate, dimethyl-(2,4-pentane-dionato) gold (III), nickel carbonyl, iron carbonyl, tin acetylacetonate, indium-acetylacetonate and indium tetramethylheptanedionate, nitrous acid, or combinations thereof. In embodiments, coating the particles involves the reaction of plasma species to form a thin layer of coating material the surface of the particles. In embodiments, this reaction can take place in the gaseous phase wherein monomers polymerize, which gives rise to a layer which deposits on the particles. In embodiments, the reaction takes place on the particle itself, wherein the coating material reacts with free radicals on the surface of the particles. This technique modifies the surface of the particles, which may in embodiments give the particles new functionalities. In embodiments of the present method, the particles are coated uniformly. It is contemplated that the thickness of the coating material on the particles is greater than or equal to about 0.1 nm to less than or equal to about 100 nm, for example about 0.1 nm, about 0.5 nm, about 1 nm, about 2 nm, about 3 nm, about 4 nm, about 5 nm, about 6 nm, about 7 nm, about 8 nm, about 9 nm, about 10 nm, about 20 nm, about 30 nm, about 40 nm, about 50 nm, about 60 nm, about 70 nm, about 80 nm, about 90 nm, about 100 nm, or any value contained within a range formed by any two of the preceding values.

In embodiments, functionalizing the surface of the particles includes increasing the hydrophobicity, hydrophilicity, surface activation, or other property of the surface of the particles relative to unmodified particles. In embodiments, functionalizing the surface of the particles includes decreasing the hydrophobicity, hydrophilicity, or surface activation of the surface of the particles relative to unmodified particles. In embodiments, functionalizing the surface of the particles allows the energetic species of the plasma to react, by addition or substitution reactions, with the surface of the particles without affecting the underlying layers. Without wishing to be bound be theory, functionalizing the surface of the particles may change the properties of the particles but does not significantly change the overall chemical composition of the particles.

In embodiments, etching the surface of the particles includes removing some of the surface layer of the particles, such that the etching occurs only on a portion of the surface of the particles. In embodiments, the particles may be cleaned, which refers to the removal of the entirety of the surface layer of the particles to yield a new, refreshed surface which is in embodiments considered to be decontaminated and/or sterilized.

In embodiments, treating the particles 206 includes exposing the particles and a modifier (such as a coating material or other reactant) to a dielectric barrier discharge as described herein. In embodiments, step 206 of the disclosed method includes treating the particles multiple times. For example, the particles may be coated with a coated material and subsequently the surface of the particles functionalized may be functionalized, or vice versa. In embodiments, treating the particles multiple times forms multifunctional particles.

In embodiments, collecting the particles 208 includes removing the modified particles from the reactor. Collecting the particles may be carried out via any method known to those skilled in the art.

In embodiments, the above embodiments may be practiced in combination. For example, the method of modifying particles as described herein is carried out in the cascade reactor as described herein. It is contemplated that parameters such as flow rate, concentration of particles, duration of time in the reactor, or other parameters may be varied depending on the particles used and the type of modification performed, and that one skilled in the art could select such parameters.

### EXAMPLES

The following non-limiting examples were carried out according to embodiments of the present disclosure.

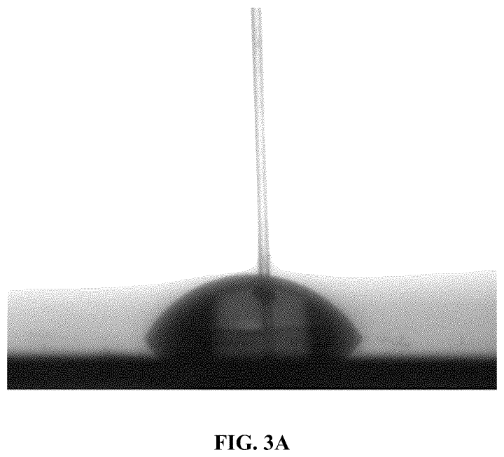

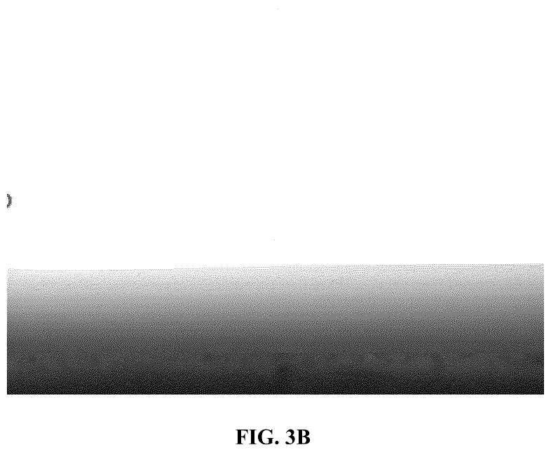

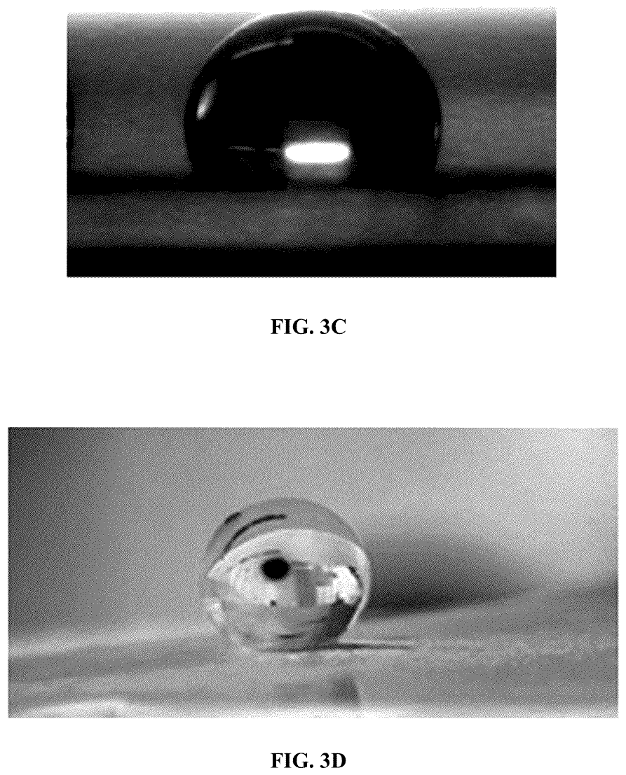

Silicon dioxide nanoparticles were treated in the method of the present disclosure. A layer of treated nanoparticles, which were prepared using the cascade reactor as described herein, was lightly pressed between two glass slides to provide an even layer of nanoparticles without damaging the surfaces thereof. The water contact angle of the layers of untreated and treated nanoparticles were then evaluated. FIG. 3A is an image of a water droplet on a surface of untreated silicon dioxide nanoparticles. The water contact angle of the surface in FIG. 3A was 57°. FIG. 3B is an image of a water droplet on a surface of modified silicon dioxide nanoparticles, according to an embodiment of the present disclosure. The surface in FIG. 3B was prepared with silicon dioxide nanoparticles modified with NH₃-plasma, and had a water contact angle of less than 5°. The contact angle significantly decreased in the NH₃-plasma modified silicon dioxide nanoparticles relative to untreated nanoparticles, and as shown, the water droplet completely disperses across the surface rather than remaining a droplet. It is contemplated that this decrease in contact angle is attributable to surface etching, without wishing to be bound by theory. FIG. 3C is an image of a water droplet on a surface of modified silicon dioxide nanoparticles, according to an embodiment of the present disclosure. The surface in FIG. 3C was prepared with silicon dioxide nanoparticles modified with Ar—CH₄ plasma, and the contact angle was greater than 90°, an increase relative to the untreated particles. FIG. 3D is an image of a water droplet on a surface of modified silicon dioxide nanoparticles, according to an embodiment of the present disclosure. The surface in FIG. 3D was prepared with Ar—SiH₄ plasma. The surface prepared with Ar—SiH₄ plasma modified particles yielded the highest contact angle at greater than 150°.

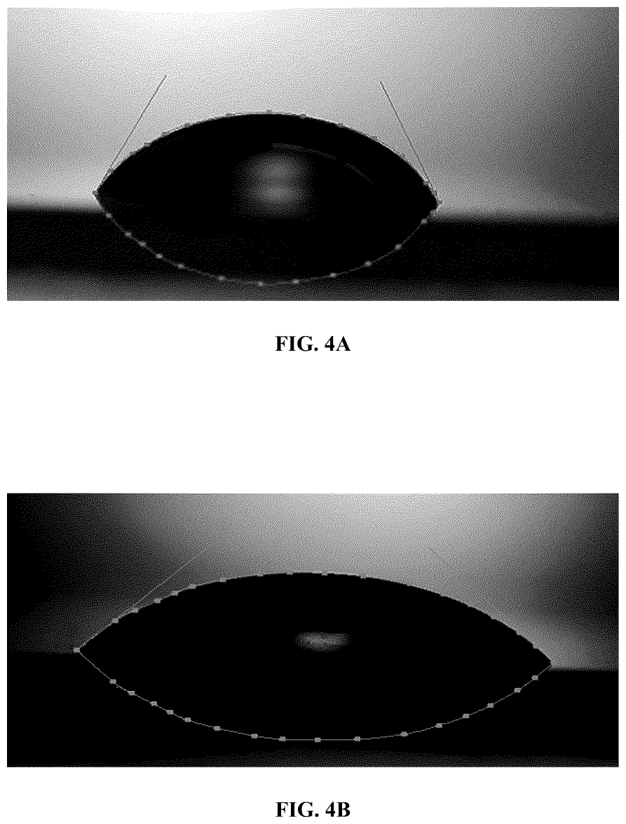

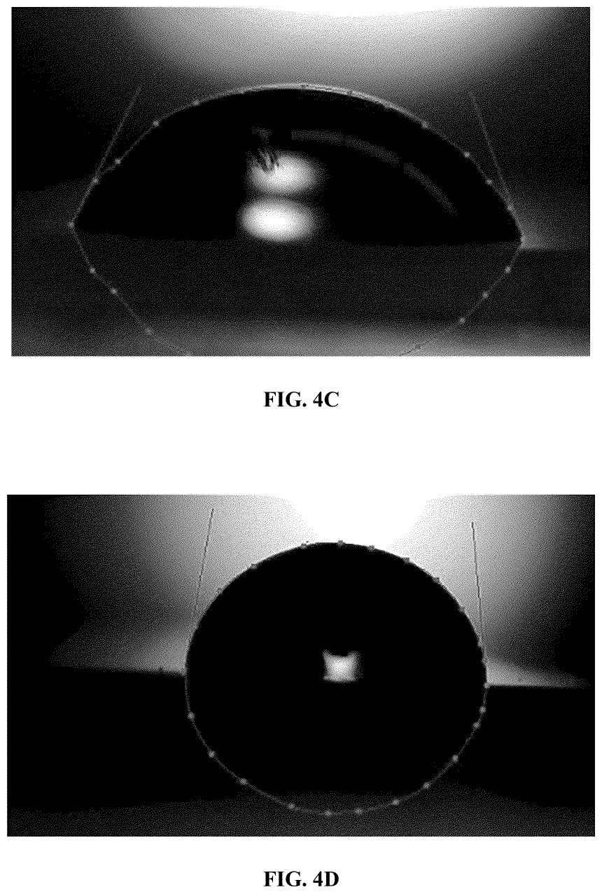

Titanium dioxide nanoparticles were also treated using the cascade reactor of the present disclosure. A layer of treated nanoparticles, which were prepared using the cascade reactor as described herein, was lightly pressed between two glass slides to provide an even layer of nanoparticles. FIG. 4A is an image of a water droplet on a surface of untreated titanium dioxide nanoparticles. The water contact angle of the surface in FIG. 4A was 67°. FIG. 4B is an image of a water droplet on a surface of modified titanium dioxide nanoparticles, according to an embodiment of the present disclosure. The surface in FIG. 4B was prepared with titanium dioxide nanoparticles modified with NH₃-plasma, and had a water contact angle of 45°. The contact angle significantly decreased in the NH₃-plasma modified titanium dioxide nanoparticles relative to untreated nanoparticles. It is contemplated that this decrease in contact angle is attributable to surface etching, without wishing to be bound by theory.

FIG. 4C is an image of a water droplet on a surface of modified titanium dioxide nanoparticles, according to an embodiment of the present disclosure. The surface in FIG. 4C was prepared with titanium dioxide nanoparticles modified first with NH₃-plasma and subsequently with Ar—CH₄ plasma, and as shown, the contact angle was 68°. It is contemplated that the water contact angle decreased due to surface etching by the NH₃-plasma and increased by the treatment with Ar—CH₄ plasma, returning the contact angle to that of the unmodified particles.

FIG. 4D is an image of a water droplet on a surface of modified titanium dioxide nanoparticles, according to an embodiment of the present disclosure. The surface in FIG. 4D was prepared with titanium dioxide nanoparticles modified first with NH₃-plasma and subsequently with Ar—SiH₄ plasma, and as shown, the contact angle was 82°. Similar to the surface of FIG. 4C, the water contact angle was decreased due to surface etching by the NH₃-plasma and increased by the treatment with Ar—SiH₄ plasma. The surfaces in FIG. 4C and FIG. 4D demonstrate the ability finely influence the properties of the modified particles using combinations of surface modifications as described herein. It should be noted that the superimposed lines and points shown in FIGS. 4A to 4D are artifacts of the surface contact angle measurement system.

Without wishing to be bound by theory, this example supports the ability to effectively modify nanoparticles (such as to influence hydrophobicity, as in this example) using the reactor and methods of the present disclosure.

This disclosure is not limited to the particular systems, devices and methods described, as these may vary. The terminology used in the description is for the purpose of describing the particular versions or embodiments only and is not intended to limit the scope.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” et cetera). While various compositions, methods, and devices are described in terms of “comprising” various components or steps (interpreted as meaning “including, but not limited to”), the compositions, methods, and devices can also “consist essentially of” or “consist of”' the various components and steps, and such terminology should be interpreted as defining essentially closed-member groups. It will be further understood by those within the art that if a specific number of an introduced claim recitation is intended, such an intent will be explicitly recited in the claim, and in the absence of such recitation no such intent is present.

For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, et cetera” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, et cetera). In those instances where a convention analogous to “at least one of A, B, or C, et cetera” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, et cetera). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, et cetera. As a non-limiting example, each range discussed herein can be readily broken down into a lower third, middle third and upper third, et cetera. As will also be understood by one skilled in the art all language such as “up to,” “at least,” and the like include the number recited and refer to ranges that can be subsequently broken down into subranges as discussed above. Finally, as will be understood by one skilled in the art, a range includes each individual member. Thus, for example, a group having 1-3 compounds refers to groups having 1, 2, or 3 compounds. Similarly, a group having 1-5 compounds refers to groups having 1, 2, 3, 4, or 5 compounds, and so forth.

Various of the above-disclosed and other features and functions, or alternatives thereof, may be combined into many other different systems or applications. Various presently unforeseen or unanticipated alternatives, modifications, variations, or improvements therein may be subsequently made by those skilled in the art, each of which is also intended to be encompassed by the disclosed embodiments.

What is claimed is:

1. A cascade reactor, comprising:
a first reactor sector comprising:
a first starting material inlet,
a first modifier inlet,
a first dielectric barrier discharge, and
a first collection outlet;
a second reactor sector, connected to the first reactor sector by a connection, comprising:
a second starting material inlet,
a second modifier inlet,
a second dielectric barrier discharge, and
a second collection outlet;
an insulating reactor support surrounding the first reactor sector and the second reactor sector,
a gas line for providing a gas to the first reactor sector and the second reactor sector, and
a housing enclosing the first reactor sector, the second reactor sector, and the gas line.

2. The cascade reactor of claim 1, wherein the first starting material inlet and the second starting material inlet each independently comprise a worm screw system, a sonication system, a tapping system, a powder sieving and blending system, or combinations thereof.

3. The cascade reactor of claim 1, wherein the first dielectric barrier discharge and the second dielectric barrier discharge each comprise a first electrode, a second electrode, and a dielectric material.

4. The cascade reactor of claim 3, wherein the first electrode and the second electrode each independently comprise a metal plate, a metal foil, a metal wire, a metal mesh, a metal spiral, a metal bolt, or a metallic paint.

5. The cascade reactor of claim 3, wherein the first electrode is a high voltage electrode.

6. The cascade reactor of claim 3, wherein the second electrode is a grounded electrode.

7. The cascade reactor of claim 1, further comprising:
a third reactor sector, enclosed within the housing and surrounded by the insulating reactor support, comprising:
a third starting material inlet,
a third modifier inlet,
a third dielectric barrier discharge, and
a third collection outlet.

8. The cascade reactor of claim 7, wherein the third dielectric barrier discharge comprises a first electrode and a second electrode.

9. A method of operating the cascade reactor of claim 1, comprising:
introducing particles into the cascade reactor,
treating the particles to form modified particles, and
collecting the modified particles.

10. The method of claim 9, wherein the particles are microparticles, nanoparticles, or combinations thereof.

11. The method of claim 9, wherein treating the particles comprises coating the particles with a coating material, functionalizing the surface of the particles, etching the particles, cleaning the particles, or combinations thereof.

12. The method of claim 9, wherein collecting the particles comprises removing the particles from the cascade reactor.

13. A method of modifying particles, comprising:
introducing the particles into a reactor,
generating a dielectric barrier discharge plasma at atmospheric pressure within the reactor,
performing a first treatment on the particles with the dielectric barrier discharge plasma to form modified particles, and
collecting the modified particles.

14. The method of claim 13, wherein the particles are microparticles, nanoparticles, or combinations thereof.

15. The method of claim 13, wherein the particles comprise silica, cellulose, polymers, titanium dioxide, carbon nanotubes, or combinations thereof.

16. The method of claim 13, wherein the first treatment comprises coating the particles with a coating material, functionalizing the surface of the particles, etching the particles, cleaning the particles, or combinations thereof.

17. The method of claim 16, wherein the coating material comprises methane, ammonia, silane, acetylene, ethylene, isoprene, hexamethyldisiloxane, tetraethyloxysilane, tetraethyl oxysilicane, diethyl dimethyl siloxane, 1,3-butadiene, styrene, methyl methacrylate, tetrafluoroethelyne, methane, ethane, propane, butane, pentane, hexane, cyclohexane, acetylene, ethylene, propylene, benzene, isoprene, hexamethyldisiloxane, tetraethyloxysilane, tetraethyl oxysilicane, diethyl dimethyl siloxane, 1,3-butadiene, styrene, methyl methacrylate, tetrafluoroethelyne, pyrrole, cyclohexane, 1-hexene, allylamine, acetyl acetone, ethylene oxide, glycidyl methacrylate, acetonitrile, tetrahydrofuran, ethyl acetate, acetic anhydride, aminopropyl trimethoxysilane, aminopropyl triethoxysilane, triethoxyvinyl silane, loctanol, acrylic acid, ferrocene, cobaltocene, cyclooctatetraene iron tricarbonyl, methyl cyclopentadienyl iron dicarbonyl, dicyclopentadienyl iron dicarbonyl dimmer, cyclopentadienyl cobalt, cobalt acetylacetonate, nickel acetylacetonate, dimethyl-(2,4-pentane-dionato) gold (III), nickel carbonyl, iron carbonyl, tin acetylacetonate, indium-acetylacetonate and indium tetramethylheptanedionate, nitrous acid, or combinations thereof.

18. The method of claim 16, wherein functionalizing the surface of the particles comprises increasing the hydrophobicity, hydrophilicity, or surface activation of the surface of the particles relative to unmodified particles.

19. The method of claim 16, wherein functionalizing the surface of the particles comprises decreasing the hydrophobicity, hydrophilicity, or surface activation of the surface of the particles relative to unmodified particles.

20. The method of claim 13, wherein collecting the particles comprises removing the particles from the reactor.

21. The method of claim 13, further comprising performing a second treatment on the particles with the dielectric barrier discharge plasma.
